(19) United States
(12) Patent Application Publication
(10) Pub. No.: US 2022/0082458 A1
(43) Pub. Date: Mar. 17, 2022

(54) FLEXIBLE SENSOR

(71) Applicant: NIKON CORPORATION, Tokyo (JP)

(72) Inventors: Shohei KOIZUMI, Atsugi-shi (JP); Yoshiaki KITO, Kamakura-shi (JP); Takachika SHIMOYAMA, Yokohama-shi (JP); Katsuhiro HATAYAMA, Tokyo (JP); Kentaro YAMADA, Fujisawa-shi (JP); Tohru KIUCHI, Niiza-shi (JP); Yasuteru FUKAWA, Tokyo (JP)

(73) Assignee: NIKON CORPORATION, Tokyo (JP)

(21) Appl. No.: 17/533,293

(22) Filed: Nov. 23, 2021

Related U.S. Application Data
(63) Continuation of application No. PCT/JP2020/021006, filed on May 27, 2020.

(30) Foreign Application Priority Data
May 30, 2019 (JP) 2019-100860

(51) Int. Cl. G01L 1/22; H01L 29/786; H01L 27/12; H01L 51/05; H01L 51/10; H01L 29/417; H01L 29/423

(52) U.S. Cl. CPC G01L 1/2293; H01L 29/7869; H01L 27/124; H01L 29/42384; H01L 51/105; H01L 29/41733; H01L 51/0558

(57) ABSTRACT

A flexible sensor includes a substrate having flexibility; and a sensor element provided on the substrate, wherein the sensor element includes a transistor having a gate electrode, a source electrode, and a drain electrode; and a variable resistance portion connected to either of the gate electrode, the source electrode, and the drain electrode, and the variable resistance portion has a resistance value changeable due to a strain, and wherein the variable resistance portion includes an extension portion extending in a direction.

### TECHNICAL FIELD

The present invention relates to a flexible sensor.

The present application is a continuation application based on a PCT International Application No. PCT/JP2020/021006, filed on May 27, 2020, whose priority is claimed on a Japanese Patent Application No. 2019-100860, filed on May 30, 2019. The contents of both the PCT International Application and the Japanese Patent Application are incorporated herein by reference.

### BACKGROUND ART

A flexible sensor having flexibility is known. For example, in Japanese Unexamined Patent Application, First Publication No. H11-241903, such a flexible sensor is disclosed as a strain sensor. The strain sensor is a configuration formed by configuring a composition in which conducting particles are dispersed into a polymeric material such as plastic, rubber, or the like in layers on a substrate, and the strain sensor is configured to measure the strain due to the deformation of the measurement target object (a steel frame structure, or a reinforced concrete structure) attached to the substrate by utilizing the characteristic that the electric resistance of the composition changes due to the extension of the composition together with the substrate. Such a flexible sensor is not only capable of measuring a one-dimensional extension measurement of the measurement target object, but also capable of simply measuring the two-dimensional strain (deformation) of a surface of the measurement target object or a two-dimensional velocity distribution of a fluid by improving the detection accuracy and the detection sensitivity.

### SUMMARY

According to an aspect of the present disclosure, a flexible sensor includes a substrate having flexibility, and a sensor element provided on the substrate, wherein the sensor includes a transistor having a gate electrode, a source electrode, and a drain electrode, and a variable resistance portion connected to one of the gate electrode, the source electrode, and the drain electrode, and the variable resistance portion includes an extension portion extending along a direction.

### BRIEF DESCRIPTION OF DRAWINGS

FIG. 1 is a perspective view showing a flexible sensor according to a first embodiment.

FIG. 2 is a planar view showing a sensor main body according to the first embodiment.

FIG. 3 is a circuit diagram showing part of the circuit configuration of the flexible sensor according to the first embodiment.

FIG. 4 is circuit diagram showing the circuit configuration of the sensor main body according to the first embodiment.

FIG. 5 is a cross-sectional view showing part of the sensor main body according to the first embodiment.

FIG. 6 is a cross-sectional view showing part of the sensor main body according to the first embodiment, and FIG. 6 is a cross-sectional view along VI-VI in FIG. 5.

FIG. 7 is a cross-sectional view showing part of the sensor main body according to the first embodiment, and FIG. 6 is a cross-sectional view along VII-VII in FIG. 5.

FIG. 8 is a view schematically showing a configuration of a controller according to the first embodiment.

FIG. 9 is a planar view showing a sensor main body according to a second embodiment.

FIG. 10 is an exploded perspective view of a sensor main body according to a third embodiment.

FIG. 11 is a planar view showing a sensor main body according to a fourth embodiment.

FIG. 12 is a circuit diagram showing part of the circuit configuration of a flexible sensor according to the fourth embodiment.

FIG. 13 is a cross-sectional view showing a transistor according to a first modification.

FIG. 14 is a cross-sectional view showing a transistor according to a second modification.

### DESCRIPTION OF EMBODIMENT

Hereinafter, a flexible sensor according to several embodiments of the present disclosure will be described with reference to the figures.

The scope of the present disclosure is not limited to the following embodiments, and the scope of the present disclosure may be arbitrarily changed within the scope of the technical idea of the present disclosure. In the following figures, the scale and the number of each configuration may be different from the scale and the number of the actual configuration in order to make each configuration easy to understand.

### First Embodiment

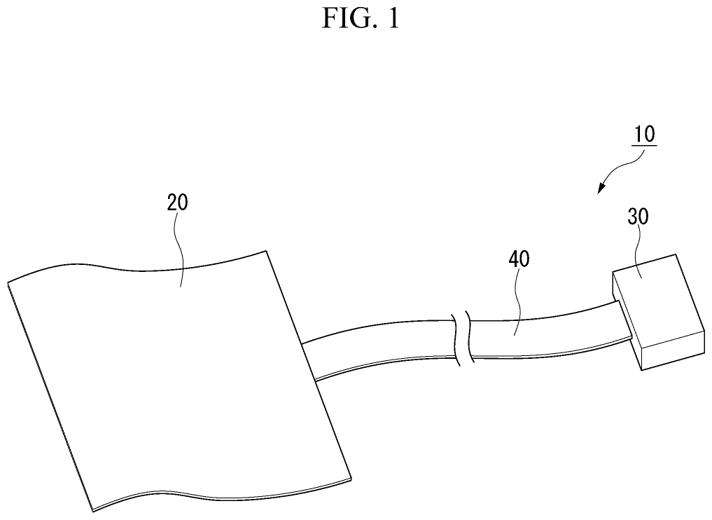

FIG. 1 is a perspective view showing a flexible sensor 10 according to the present embodiment.

The flexible sensor 10 according to the present embodiment may be a strain sensor configured to measure the strain of a measurement target object. As shown in FIG. 1, The flexible sensor 10 according to the present embodiment includes a sensor main body 20 stuck to the measurement target object for measuring the strain, a wiring portion 40 extending from the sensor main body 20, and a control unit (measurement unit) 30 connected to the sensor main body 20 via the wiring portion 40.

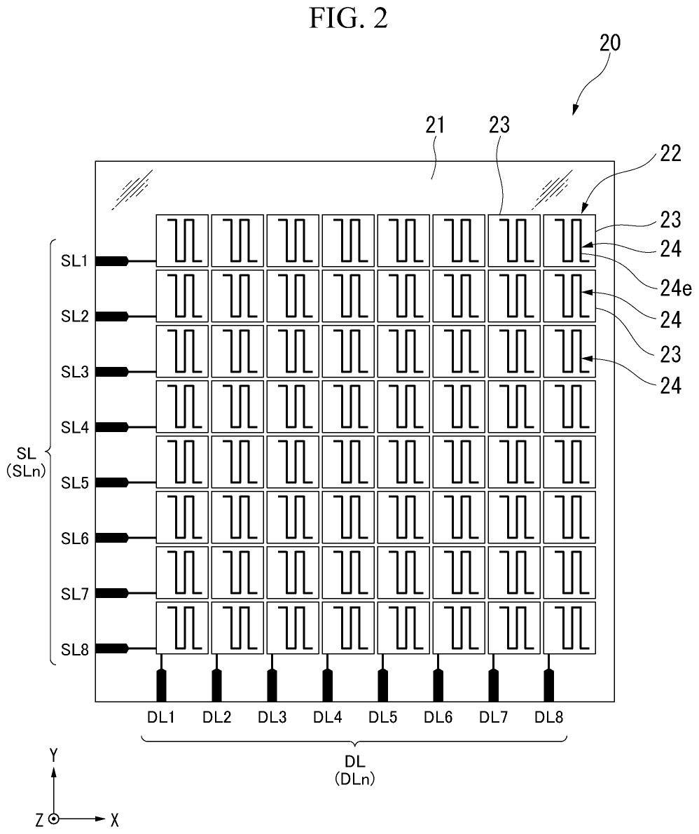

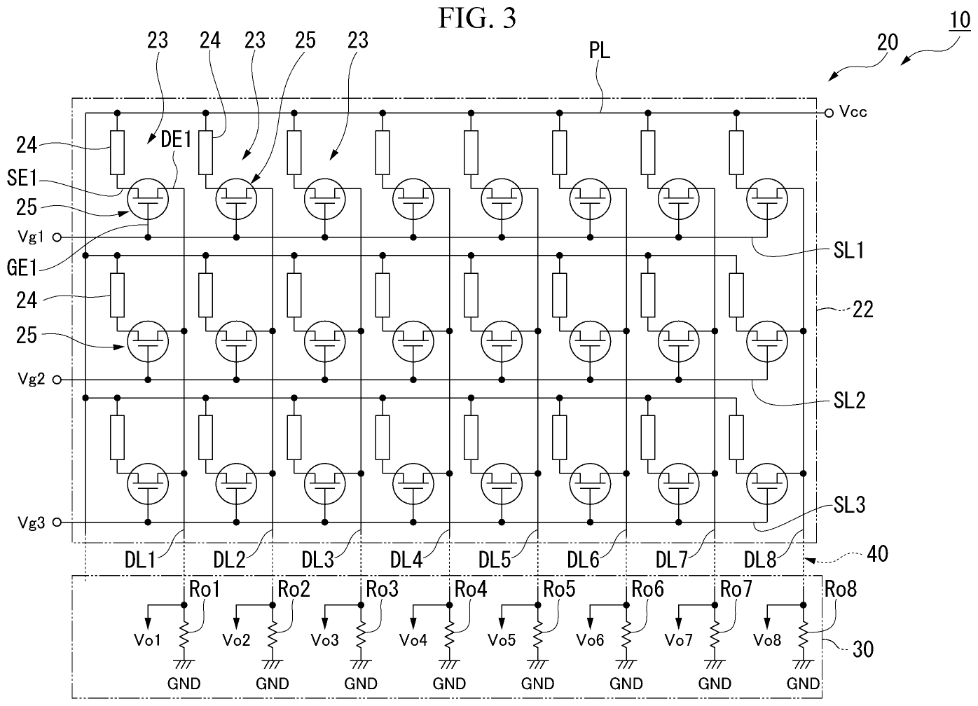

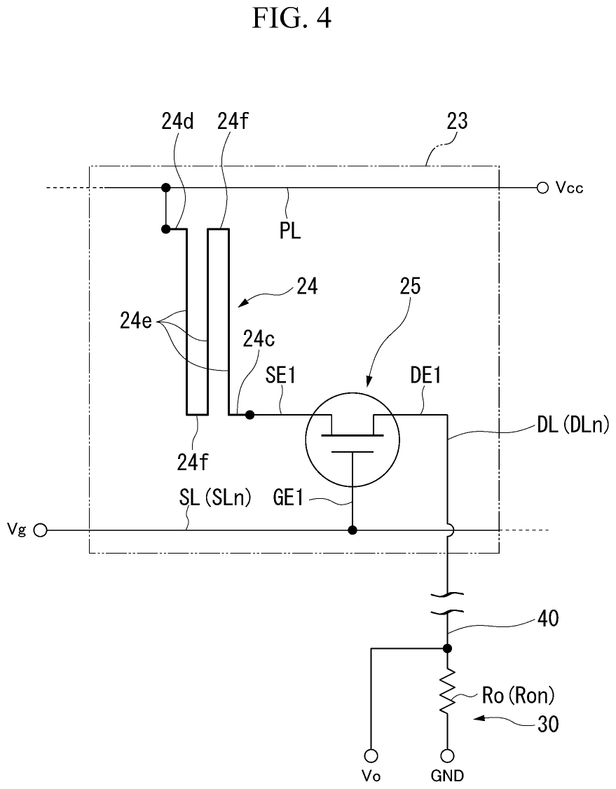

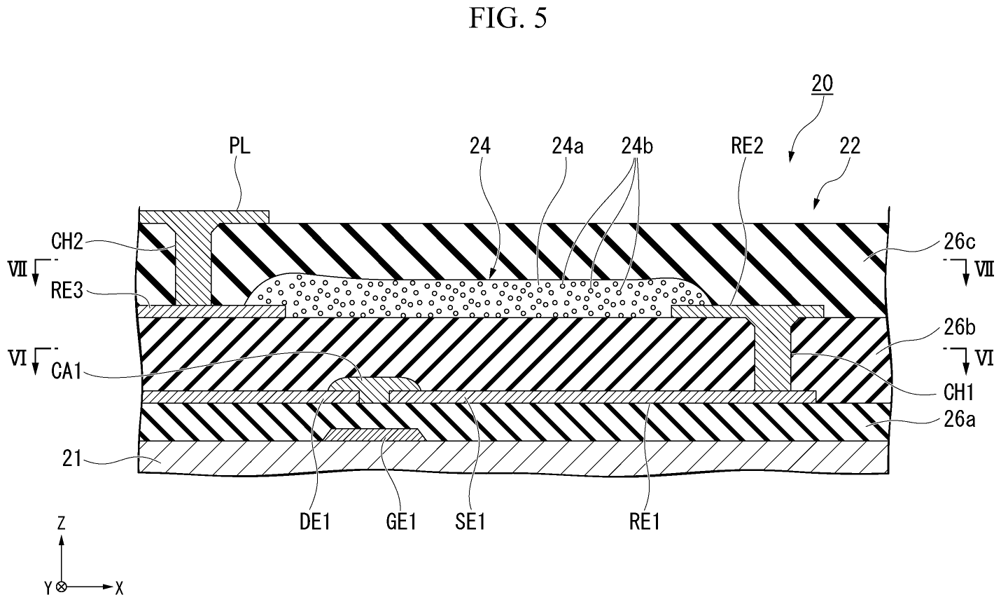

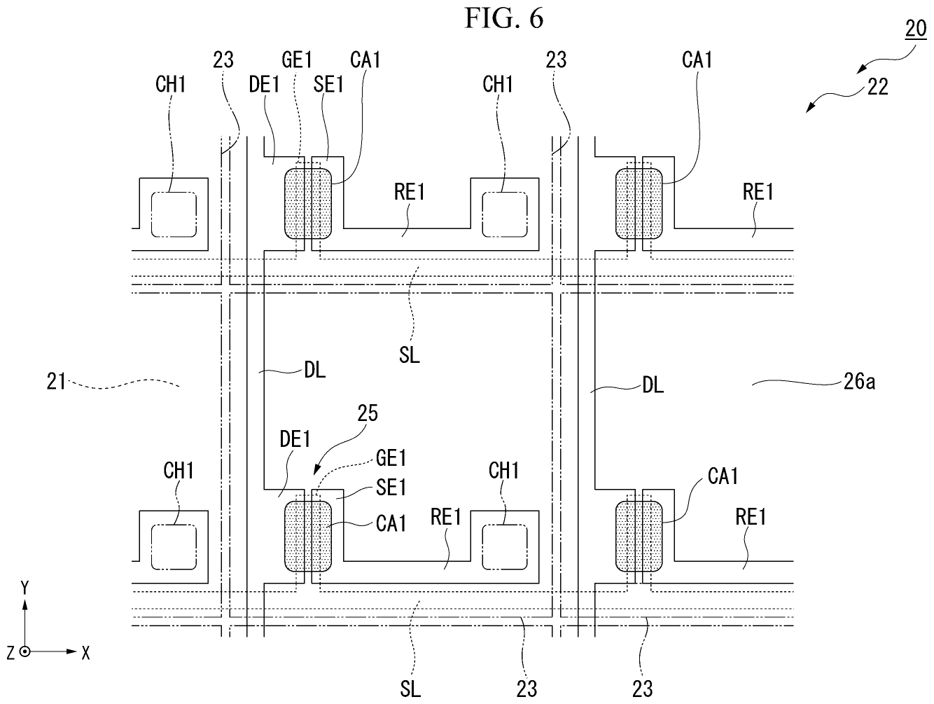

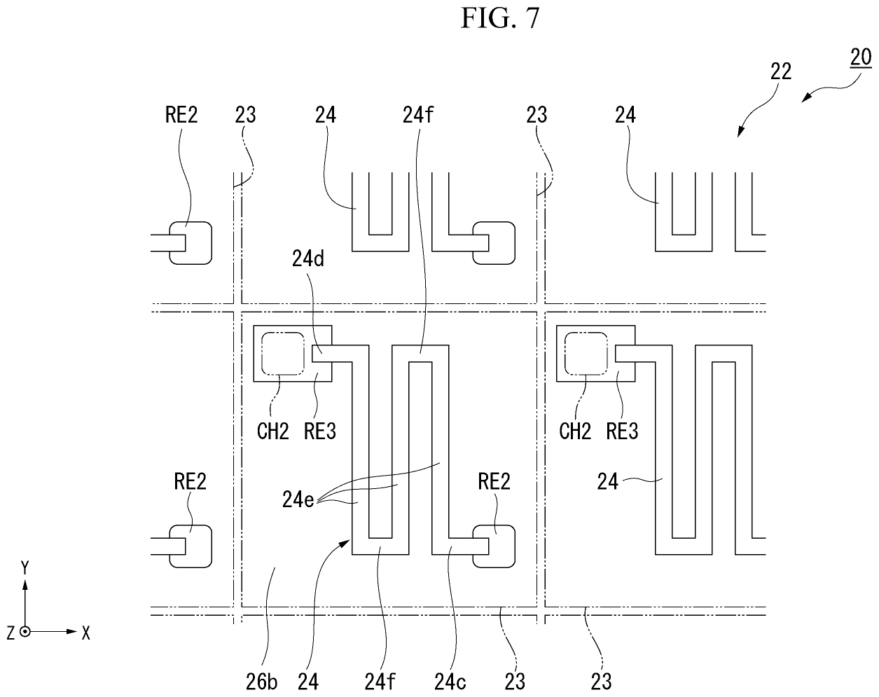

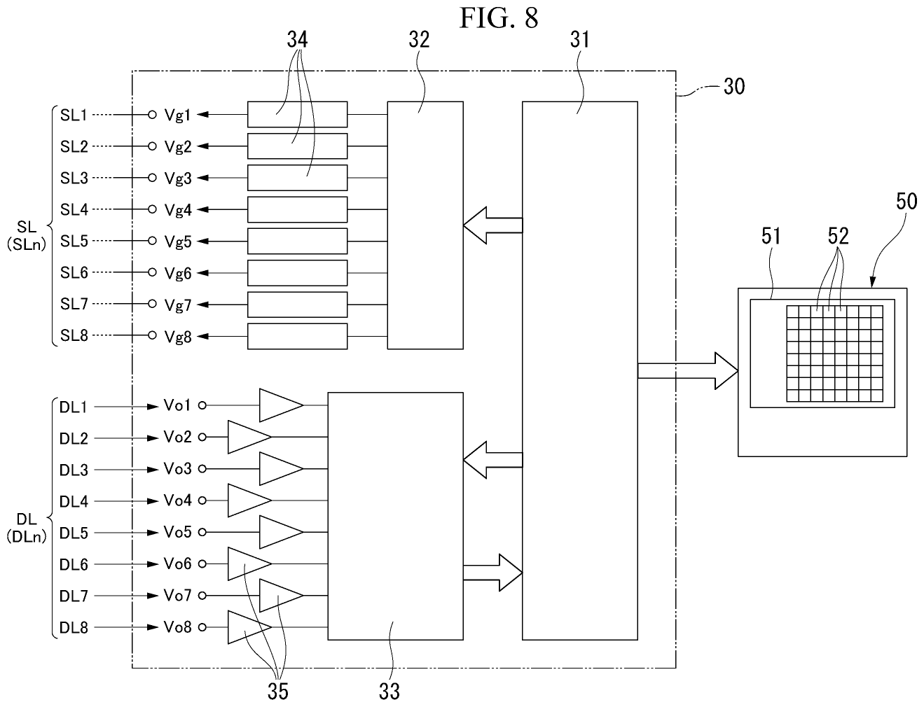

FIG. 2 is a planar view showing the sensor main body 20. FIG. 3 is a circuit diagram showing part of the circuit configuration of the flexible sensor 10. FIG. 4 is a circuit diagram showing the circuit configuration of a sensor element 23 in the sensor main body 20. FIG. 5 is a cross-sectional view showing part of the sensor main body 20. FIG. 6 is a cross-sectional view showing part of the sensor main body 20, and FIG. 6 is a cross-sectional view along the line VI-VI in FIG. 5. FIG. 7 is a cross-sectional view showing part of the sensor main body 20, and FIG. 6 is a cross-sectional view along the line VII-VII in FIG. 5. FIG. 8 is a view schematically showing the configuration of the control unit 30.

The sensor main body 20 has flexibility. As shown in FIG. 2, the sensor main body 20 includes a substrate 21 and a sensor unit 22. The substrate 21 has the flexibility. The flexibility of the substrate 21 in the present description refers to a property that the substrate 21 can be flexed and elastically deformed without being sheared or broken even when a force close to the own weight thereof is applied to the substrate 21. The flexibility of the substrate 21 also includes the property of bending by a force close to the own weight thereof. Therefore, the substrate 21 is made of a base material having a rigidity (Young's modulus) so as to return to an original flat state when the external force is withdrawn in a casein which the substrate 21 is bent from the flat state by the external force within a range of elastic deformation. The flexibility of the substrate 21 may change depending on the material, size, thickness, temperature, and other environments of the substrate 21.

For example, the base material of the substrate 21 may be a resin file such as polyacrylate, polycarbonate, polyurethane, polystyrene, cellulose polymer, polyolefin, polyamide, polyimide, polyester, polyphenylene, polyethylene, polyethylene terephthalate (PET), polyethylene naphthalate (PEN), polypropylene, ethylene-vinyl copolymer film, polyvinyl chloride, or the like, or a thin plate made of glass, sapphire, metal, cellulose nanofibers or the like that is processed to a thin plate having a thickness of several tens of micro meters to several hundreds of micro meters.

For example, the substrate 21 according to the present embodiment is the resin film formed in a square shape. The shape of the substrate 21 is not limited to the square shape, and a triangular shape, a rectangular shape, a rhombus shape, a polygonal shape equal to or more than a pentagon, a circular shape, an elliptical shape, or the like.

In each figure, the X-axis direction, the Y-axis direction, and the Z-axis direction are appropriately shown with reference to the substrate 21 in a state without any deformation. The Z-axis direction indicates a thickness direction of the substrate 21. The X-axis direction indicates a direction parallel to one side of the square substrate 21. The Y-axis direction indicates a direction parallel to another side of the square substrate 21 extending in a direction different from the X-axis direction. The X-axis direction, the Y-axis direction, and the Z-axis direction are orthogonal to each other.

In the following description, the direction parallel to the Z-axis direction is referred to as a “thickness direction”, the direction parallel to the X-axis direction is referred to as a “first direction”, and the direction parallel to the Y-axis direction is referred to as a “second direction”. Furthermore, the positive side (+Z side) in the Z-axis direction is referred to as an “upper side”, and the negative side (−Z side) in the Z-axis direction is referred to as a “lower side”. Furthermore, the positive side (+X side) in the X-axis direction is referred to as “one side in the first direction”, and the negative side (−X side) in the X-axis direction is referred to as “the other side in the first direction”. Furthermore, the positive side (+Y side) in the Y-axis direction is referred to as “one side in the second direction”, and the negative side (−Y side) in the Y-axis direction is referred to as “the other side in the second direction”.

The sensor portion is a portion capable of detecting the stain of the measurement target object to which the sensor main body 20 is stuck. The sensor unit 22 is provided in the plane at the upper side (+Z side) of the substrate 21. As shown in FIG. 2 and FIG. 3, the sensor unit 22 include a plurality of sensor elements 23, a plurality of scan lines SL, a plurality of signal lines DL, and a power electrode (wiring for power) PL.

The sensor unit 22 according to the present embodiment is an active-matrix type sensor portion in which the plurality of sensor elements 23 are arranged in a matrix shape. The plurality of sensor elements 23 are arranged in the matrix shape along the first direction (X-axis direction) and the second direction (Y-axis direction). In the example shown in FIG. 2, the sensor elements 23 are arranged in the matrix shape having 8 rows and 8 columns, and a total of 64 sensor elements 23 are provided therein.

The plurality of sensor elements 23 are provided on the substrate 21. Each sensor element 23, as shown in FIG. 3 and FIG. 4, includes a transistor 25 and a variable resistance portion 24 . The transistor 25 is a Field Effect Transistor (FET) including a gate electrode GE1, a source electrode SE1, and a drain electrode DE1. The transistor 25 according to the present embodiment is a Thin Film Transistor (TFT). For example, the transistor 25 is an Organic Thin Film Transistor (OTFT).

As shown in FIG. 5, the transistor 25 according to the present embodiment includes a P-type channel CA1. According to the present embodiment, a material of the channel CA1 is, for example, an organic semiconductor. Examples of the organic semiconductors include copper phthalocyanine (CuPc), pentacene, rubrene, tetracene, 6,13-bis (triisopropylsilylethynyl) pentacene (TIPS pentacene), and poly (3-hexylthiophene-2,5-diyl) (P3HT) and the like. The organic semiconductor that can be used as the material of the channel CA1 is not limited to the above-mentioned material.

The material of channel CA1 may be an inorganic semiconductor. As the inorganic semiconductor, for example, zinc oxide (ZnO), an oxide containing In, Ga and Zn (InGaZnO 4: IGZO), amorphous silicon, low-temperature polysilicon and the like can be used. The inorganic semiconductor that can be used as the material of the channel CA1 is not limited to the above-mentioned material.

The channel CA1 joins the source electrode SE1 and the drain electrode DE1. According to the present embodiment, the transistor 25 is, for example, a bottom-gate type and bottom-contact type transistor. According to the present embodiment, the source electrode SE1 and the drain electrode DE1 are arranged side by side in the first direction (X-axis direction). The source electrode SE1 is located, for example, at the one side (+X side) of the drain electrode DE1 in the first direction. According to the present embodiment, the transistor 25 functions as an active matrix switching element to select a variable resistance portion 24 to be measured among the variable resistance portions 24 arranged two-dimensionally at predetermined intervals in the first direction (X-axis direction) and the second direction (Y-axis direction).

The variable resistance portion 24 is a portion whose resistance value changes according to the strain (expansion and contraction due to the deflection of the substrate 21 in the thickness direction Z). According to the present embodiment, as shown in FIG. 5, the variable resistance portion 24 is formed in a film shape formed on the upper surface (+Z side) of an insulating film 26b described below. As shown in FIG. 4 and FIG. 7, the variable resistance portion 24 has a rectangular wavy shape when viewed in a plane parallel to the XY plane. The variable resistance portion 24 has a plurality of extension portions 24e, a plurality of joint portions 24f, and connecting portions 24c and 24d.

The extension portion 24e extends in one direction. In a single variable resistance portion 24, the plurality of extension portions 24e extend in the same direction with each other, and the plurality of extension portions 24e are arranged side by side at intervals in a direction orthogonal to the extending direction. According to the present embodiment, the plurality of extension portions 24e extend in the second direction (Y-axis direction). That is, the direction in which the extension portions 24e extend is orthogonal to the direction in which the source electrode SE1 and the drain electrode DE1 are arranged.

According to the present embodiment, the extension portion 24e extends in the second direction (Y-axis direction) in the variable resistance portion 24 of each sensor element 23. That is, in the plurality of sensor elements 23 included in the sensor unit 22, the extension portions 24e of the variable resistance portion 24 extend in the same direction.

In addition, in the present specification, the recitation “a plurality of extension portions extend in the same direction” includes the case in which the plurality of extension portions extend in substantially the same direction in addition to the case in which the plurality of extension portions extend in exactly the same direction. As an example, the recitation “a plurality of extension portions extend in substantially the same direction with each other” includes a case in which a deviation of the extending direction of an extension portion from the extending direction of another extension portion is equal to or less than 10 degrees.

For example, three extension portions 24e are provided in each variable resistance portion 24. According to the present embodiment, the plurality of extension portions 24e are arranged side by side at equal intervals. The distance between the adjacent extension portions 24e is shorter than a length of the extension portions 24e. According to the present embodiment, the length of the extension portion 24e is a dimension of the extension portion 24e in the second direction (Y-axis direction).

According to the present specification, the recitation “a plurality of extension portions are arranged side by side at equal intervals” includes the case in which the interval between the adjacent extension portions is substantially the same in addition to the case in which the interval between the adjacent extension portions is exactly the same. As an example, the recitation “the interval between the adjacent extension portions is substantially the same” includes the case in which a difference between the interval between a pair of the extension portions and the interval between another pair of extension portions is equal to or less than 10%.

The joint portion 24f extends in the first direction (X-axis direction) and joins the end portions of the adjacent extending portions 24e. For example, two joint portions 24f are provided therein. One joint portion 24f joins the end portions at the one side (+Y side) in the second direction of the central extension portion 24e and the extension portion 24e located at the one side (+X side) in the first direction. The other joint portion 24f joins the end portions at the other side (−Y side) in the second direction of the central extension portion 24e and the extension portion 24e at the other side (−X side) in the first direction. As a result, the variable resistance portion 24 is formed in a rectangular wavy shape by joining the adjacent extension portions 24e to each other. A length of the joint portion 24f is the same with the interval between the extension portions 24e, and is shorter than the length of the extension portion 24e. According to the present embodiment, the length of the joint portion 24f is the dimension of the joint portion 24f in the first direction (X-axis direction).

The connecting portion 24c is an end portion of the variable resistance portion 24. The connecting portion 24c extends from the end portion at the other side (−Y side) in the second direction of the extension portion 24e at the one side (+X side) in the first direction to the one side in the first direction. As shown in FIG. 4, the connecting portion 24c is connected to the source electrode SE1 of the transistor 25. As a result, the variable resistance portion 24 is connected to the source electrode SE1 of the transistor 25. More specifically, the variable resistor portion 24 is connected in series with the source electrode SE1.

The connecting portion 24d is the other end portion of the variable resistance portion 24. As shown in FIG. 7, the connecting portion 24d extends from the end portion at the one side (+Y side) in the second direction of the extension portion 24e at the other side (−X side) in the first direction to the other side in the first direction. As shown in FIG. 4, the connecting portion 24d is connected to the power supply electrode PL. As a result, the variable resistance portion 24 is connected to the power supply electrode PL.

According to the present embodiment, the variable resistance portion 24 has an insulator 24a and a plurality of conductive particles 24b dispersed in the insulator 24a, as shown in an exaggerated manner in FIG. 5. A material of the insulator 24a only has to have an insulating property, for example, a resin material such as plastic or the like and a polymer material such as rubber or the like may be used, and the material of the insulator 24a is not particularly limited. According to the present embodiment, the material of the insulator 24a is an energy curable resin. The energy curable resin is, for example, a thermosetting resin, a photocurable resin, or the like. A material of the conductive particles 24b is not particularly limited as long as it is a conductive material, and is, for example, carbon (graphite), metal, or the like.

When the strain occurred (expanded or contracted) in the variable resistance portion 24, the distance between the plurality of conductive particles 24b in the insulator 24a changes, and the conductivity of the variable resistance portion 24 changes. As a result, the resistance value of the variable resistance portion 24 changes according to the strain. More specifically, for example, in a case in which the strain occurs in the direction in which the variable resistance portion 24 is contracted, the distance between the conductive particles 24b in the insulator 24a is shortened such that the contact interface between the conductive particles 24b is increased and the resistance value of the variable resistance portion 24 decreases. On the other hand, in a case in which the strain occurs in the direction in which the variable resistance portion 24 is extended, the contact interface between the conductive particles 24b is reduced by increasing the distance between the conductive particles 2 4b in the insulator 24a, and the resistance value of the variable resistance portion 24 is increased.

For example, in a case in which the variable resistance portion 24 is formed in the film shape on the insulating film 26b as described in the present embodiment, when the sensor element 23 is bent to be convex in the lower side (−Z side), the strain in the variable resistance portion 24 occurs in the direction in which the variable resistance portion 24 is contracted and the resistance value of the variable resistance portion 24 becomes smaller. On the other hand, when the sensor main body 20 is bent to be convex in the upper side, the strain in the variable resistance portion 24 occurs in the direction in which the variable resistance portion 24 is extended and the resistance value of the variable resistance portion 24 becomes larger.

For example, the change in the resistance value of the variable resistance portion 24 changes exponentially with respect to the rate of expansion and contraction of the variable resistance portion 24 within a certain range in which the variable resistance portion 24 expands and contracts. Furthermore, for example, when the variable resistance portion 24 is contracted by a certain amount or more, there is almost no change in the resistance value of the variable resistance portion 24. This is because the distance between the conductive particles 24b is not shortened any more and the resistance value is not further reduced. Furthermore, for example, when the variable resistance portion 24 is extended beyond a certain level, there is almost no change in the resistance value of the variable resistance portion 24. This is because the distance between the conductive particles 24b becomes too long, and the resistance value of the variable resistance portion 24 is not increased any more than the current value.

The configuration “variable resistance portion” in the present specification may be made by using, for example, the sensor coating materials described in Japanese Unexamined Patent Application, First Publication No. 2009-198482 and Japanese Unexamined Patent Application, First Publication No. 2009-198483. Furthermore, the configuration “variable resistance portion” in the present specification may be made by using, for example, the pressure sensitive resistor paint described in Japanese Unexamined Patent Application, First Publication No. S60-127603, or the strain deformation resistance changing rubber described in Japanese Unexamined Patent Application, First Publication No. S62-12825, or the strain gauge resistance ink described in Japanese Unexamined Patent Application, First Publication No. H7-243805, or the ink made of the polymer material in which the conductive particles (graphite) are dispersed as described in Japanese Unexamined Patent Application, First Publication No. H11-241903.

In the variable resistance portion 24, the extension portion 24e, the joint portion 24f, and the connecting portions 24c and 24d can be formed of the same material. However, in the present embodiment, since the extension portion 24e is the portion necessary for strain (expansion and contraction) measurement, at least the extension portion 24e has the structure in which the resistance value changes, that is, the structure having the insulator 24a and the conductive particles 24b. That is, the joint portion 24f and the connecting portions 24c and 24d do not have to include the insulator 24a and the conductive particles 24b. The joint portion 24f and the connecting portions 24c and 24d may be the thin films made of a conductive material such as gold, silver, copper, aluminum, nickel-phosphorus, a conductive polymer, and the like.

As shown in FIG. 6, the plurality of scanning lines SL extend in the first direction (X-axis direction). The plurality of scanning lines SL are arranged at intervals along the second direction (Y-axis direction). As shown in FIG. 2, eight scanning lines SL1 to SL8 are provided in the present embodiment. As shown in FIG. 3, a plurality of gate electrodes GE1 of the transistor 25 are connected to each scanning line SL. More specifically, the gate electrodes GE1 of the eight sensor elements 23 in each row of the sensor elements 23 arranged in 8 rows and 8 columns are connected to the scanning lines SL1 to SL8, respectively. As shown in FIG. 2, for example, the end portions of the scanning lines SL1 to SL8 at the other side (−X side) in the first direction are provided as a terminal portion on the substrate 21.

As shown in FIG. 6, the plurality of signal line DLs extend in the second direction (Y-axis direction). The plurality of signal line DLs are arranged at intervals along the first direction (X-axis direction). As shown in FIG. 2, eight signal lines DL1 to DL8 are provided in the present embodiment. As shown in FIG. 3, a plurality of drain electrodes DE1 of the transistor 25 are connected to each signal line DL. More specifically, the drain electrodes DE1 of the eight sensor elements 23 in each column of the sensor elements 23 arranged in 8 rows and 8 columns are connected to the signal lines DL1 to DL8, respectively. As shown in FIG. 2, for example, the end portions of the signal lines DL1 to DL8 on the other side (−Y side) in the second direction are provided as a terminal portion on the substrate 21.

As shown in FIG. 5 and FIG. 6, each of the scanning lines SL1 to SL8 is formed as the same layer on the surface of the substrate 21 together with the gate electrode GE1 of each transistor 25, and each of the signal lines DL1 to DL8 together with the drain electrode DE1 and the source electrode SE1 of each transistor 25 are formed on the surface of the insulating film 26a laminated on the same layer.

As shown in FIG. 3 and FIG. 4, the signal line DL is connected to the fixed resistance portion Ro provided in the control unit 30 via the wiring portion 40. The fixed resistance portions Ro includes eight fixed resistance portions Ro1 to Ro8. Each of the fixed resistance portions Ro1 to Ro8 is connected to the signal lines DL1 to DL8, respectively. Each of the fixed resistance portions Ro1 to Ro8 is grounded to the ground GND provided in the control unit 30.

In the following description, when the scanning lines SL1 to SL8 are generically referred to, they are also referred to as the scanning line SLn, when the signal lines DL1 to DL8 are generically referred to, they are also referred to as the signal line DLn, and when the fixed resistance portions Ro1 to Ro8 are generically referred to, they are also referred to as the fixed resistance part Ron. In each of the scanning line SLn, the signal line DLn, and the fixed resistance portion Ron, the term “n” is an integer from 1 to 8.

The power supply electrode PL is an electrode to which a power supply potential having a value of Vcc is supplied from the control unit 30 via the wiring unit 40. One end side of the variable resistance portion 24 is connected to the power supply electrode PL, and the source electrode SE1 of the transistor 25 is connected to the other end side of the variable resistance portion 24. In the present embodiment, each of the source electrodes SE1 of all the sensor elements 23 included in the sensor unit 22 is individually connected to the power supply electrode PL via the variable resistance portion 24.

In the present embodiment, the power supply electrode PL is connected to the ground GND via the variable resistance portion 24, the transistor 25, the signal line DLn (n=1 to 8), the wiring portion 40, and the fixed resistance portion Ron (n=1 to 8). Therefore, a voltage corresponding to the potential difference between the power supply potential supplied to the power supply electrode PL and the ground GND, that is, the power supply voltage Vcc is applied to the variable resistance portion 24, the transistor 25, and the fixed resistance portion Ron.

As shown in FIG. 5, according to the present embodiment, each part of the sensor unit 22 described above is formed in the film shape, and the sensor unit 22 is configured by laminating a plurality of films on the substrate 21. Each part of the sensor unit 22 formed in the film shape is formed by, for example, a wet process. The sensor unit 22 further includes insulating films 26a, 26b, 26c, contact holes CH1, CH2, and relay electrodes RE1, RE2, RE3, in addition to the above-mentioned configurations.

The material of the insulating films 26a, 26b, and 26c is, for example, an insulating inorganic material such as silicon compounds. In FIG. 6, the insulating film 26b is omitted. In FIG. 7, the insulating film 26c is omitted. The scanning line SL, the signal line DL, the power supply electrode (wiring for power supply) PL, the gate electrode GE1, the source electrode SE1, the drain electrode DE1, and the relay electrodes RE1, RE2, RE3 are made of thin film of conductive materials such as gold, silver, copper, aluminum, nickel phosphorus, conductive polymer, and the like.

As shown in FIG. 5 and FIG. 6, the gate electrode GE1, the scanning line SL, and the insulating film 26a are formed on the upper surface of the substrate 21. The insulating film 26a covers the gate electrode GE1 from the upper side. According to the present embodiment, the gate electrode GE1 and the scanning line SL are made by applying the same conductive material to the upper surface of the substrate 21. In the case of applying the coating method, the gate electrode GE1 and the scanning line SL can be made by an inkjet method, a screen-printing method, or the like using a conductive ink containing conductive nanoparticles such as silver, gold, and copper or the like. Furthermore, the gate electrode GE1 and the scanning line SL may be formed by an etching method in which a metal thin film such as copper, nickel, or gold is uniformly formed on the upper surface of the substrate 21 and then the metal thin film is partially removed.

When a sheet of a conductive material such as metal is used as the base material of the substrate 21, it is necessary to provide an insulating layer between the gate electrode GE1 and the substrate 21 and between the scanning line SL and the substrate 21. The insulating layer may be made of the same material as that of the insulating films 26a, 26b, 26c, or may be made of a different material. Furthermore, the insulating layer may be provided on the entire surface of the substrate 21, or may be provided only in the region corresponding to the gate electrode GE1 and the scanning line SL on the substrate 21.

A source electrode SE1, a drain electrode DE1, a channel CA1, a signal line DL, a relay electrode RE1, and an insulating film 26b are formed on the upper surface of the insulating film 26a. The insulating film 26b covers the source electrode SE1, the drain electrode DE1, the channel CA1, the signal line DL, and the relay electrode RE1 from the upper side.

According to the present embodiment, the source electrode SE1, the drain electrode DE1, the signal line DL, and the relay electrode RE1 are made of coating the same conductive material (conductive ink or the like) on the upper surface of the insulating film 26a, or etching the metal thin film. The channel CA1 is made by applying an organic semiconductor material to the source electrode SE1 and the drain electrode DE1 from the upper side. The source electrode SE1, the drain electrode DE1, and the channel CA1 are located above the gate electrode GE1. As shown in FIG. 6, the relay electrode RE1 extends from the source electrode SE1 to the one side (+X side) in the first direction.

As shown in FIG. 5 and FIG. 7, the variable resistance portion 24, the relay electrodes RE2 and RE3, and the insulating film 26c are formed on the upper surface of the insulating film 26b. The insulating film 26c covers the variable resistance portion 24 and the relay electrodes RE2 and RE3 from the upper side. According to the present embodiment, the relay electrode RE2 and the relay electrode RE3 are made by applying the same conductive material to the upper surface of the insulating film 26b. The conductive material configuring the relay electrode RE2 and the relay electrode RE3 is, for example, the same as that of the conductive material configuring the source electrode SE1, the drain electrode DE1, the signal line DL, and the relay electrode RE1.

As shown in FIG. 5, the relay electrode RE2 is connected to the relay electrode RE1 via a contact hole CH1 that penetrates the insulating film 26b in the thickness direction Z. As shown in FIG. 6, the connecting portion 24c of the variable resistance portion 24 is connected to the relay electrode RE2. That is, according to the present embodiment, the variable resistance portion 24 is connected to the source electrode SE1 of the transistor 25 via the relay electrode RE2, the contact hole CH1, and the relay electrode RE1. The relay electrode RE3 is connected to the connecting portion 24d of the variable resistance portion 24.

As shown in FIG. 5, the power supply electrode PL is formed on the upper surface of the insulating film 26c. The power supply electrode PL is made, for example, by applying the same conductive material as the material of each electrode described above to the upper surface of the insulating film 26c, or by etching a metal thin film. The power supply electrode PL is connected to the relay electrode RE3 via a contact hole CH2 that penetrates the insulating film 26c in the thickness direction Z. That is, according to the present embodiment, the variable resistance portion 24 is connected to the power supply electrode PL via the relay electrode RE2 and the contact hole CH2. Furthermore, according to the present embodiment, the source electrode SE1 is connected to the power supply electrode PL via the variable resistance portion 24, the relay electrode RE2, and the contact hole CH2.

The wiring portion 40 may be a bundle formed by bundling a plurality of wires parallel to each other in a flat ribbon shape so as to have flexibility; however, similar to the sensor main body 20, the wiring portion 40 may be formed by forming the film-shaped wirings by the conductive materials such as gold, silver, copper, aluminum, nickel-phosphorus, conductive polymer or other conductive materials on the substrate having flexibility and then being covered by the insulative film. The wiring portion 40 electrically connects the sensor main body 20 and the control unit (measurement unit) 30. Although it is not shown in figures, the wiring portion 40 includes a plurality of wirings connected to the plurality of (8) scanning lines SL respectively and extend to the control unit 30, a plurality of wirings connected to the plurality of (8) signal, a wiring for a power supply, and a wiring for ground GND (earth).

As shown in FIG. 8, the control unit 30 includes a scanning-line drive circuit 32, an 8-channel (8ch) AD converter circuit 33, and a microcomputer 31. The plurality of scanning lines SL1 to SL8 are connected to the scanning-line drive circuit 32. The scanning-line drive circuit 32 sequentially outputs a logic level (5V system or 3V system) pulsed scanning signal to either one of the plurality of scanning lines SL1 to SL8. The scanning signal is shifted by a level shifter connected between the scanning lines SL1 to SL8 and the scanning line drive circuit 32 such that the gate potentials Vg1 to Vg8 applied to each of the scanning lines SL1 to SL8 become the appropriate voltage level corresponding to the characteristic of the transistor 25. When the scanning signal from the scanning-line drive circuit 32 is supplied to the scanning line SL as the gate potential Vg via the level shifter 34, the gate potential Vg is supplied to the gate electrode GE1 connected to the scanning line SL. As a result, the transistor 25 enter the ON state, and a current flows from the source electrode SE1 to the drain electrode DE1 via the channel CA1.

Voltages obtained by amplifying the output voltages Vo1 to Vo8 of the plurality of signal lines DL1 to DL8 by an amplifier 35 are applied to each channel of the 8ch AD converter circuit 33. As shown in the circuit configuration of FIG. 4, each of the output voltages Vo1 to Vo8 is a voltage dividing potential indicated by a product of a current value determined by the series resistance value of the variable resistance portion 24 connected to the power supply voltage Vcc applied between the power supply electrode PL and the ground GND, the on-resistance between the drain and the source of the transistor 25 in the ON state, and the fixed resistance portion Ron (n=1 to 8), and the resistance value of the fixed resistance portion Ron (n=1 to 8). The fixed resistance portion Ron (n=1 to 8) may be a configuration of connecting the variable resistor and the fixed resistor in series for the adjustment in response to the characteristics of the variable resistor portion 24 the on-resistance of the transistor 25.

Here, the resistance value of the variable resistance portion 24 changes due to the strain occurring (extension and contraction of the variable resistance portion 24 due to the bending of the substrate 21). Therefore, the output voltage Vo, which is the voltage dividing potential applied to the fixed resistance portion Ro, changes in response to the change in the resistance value of the variable resistance portion 24. When the resistance value of the variable resistance portion 24 becomes large, the voltage value applied to the fixed resistance portion Ro becomes relatively small such that the output voltage Vo becomes small. On the other hand, when the resistance value of the variable resistance portion 24 becomes small, the voltage value applied to the fixed resistance portion Ro becomes relatively large, so that the output voltage Vo becomes large. Therefore, the change in the resistance value of the variable resistance portion 24 can be obtained from the value of the output voltage Vo, and the strain occurred in the sensor element 23 can be detected.

Even in a case in which the substrate 21 is flat as a whole and locally and the variable resistance portion 24 is in a strain-free state in which the variable resistance portion 24 is not extended or contracted in the second direction (Y-axis direction), the variable resistance portion 24 has a certain resistance value. The output voltage Vo (Vo1 to Vo8) generated by the resistance value of the variable resistance portion 24 in the strain-free state is stored in the memory of the microcomputer 31 in advance as a digital value corresponding to the initial voltage value (initial value) in the strain-free state.

Each of the output voltages Vo1 to Vo8 is amplified by the amplifier 35 and input to the AD converter circuit 33. The AD converter circuit 33 converts each of the input output voltages Vo1 to Vo8 into digital data. The AD converter circuit 33 outputs the converted digital data to the microcomputer 31 based on the command from the microcomputer 31. For example, the AD converter circuit 33 encloses an analog multiplexer circuit that selects one input signal among the analog input signals of the eight channels, and sequentially converts the analog values of the output voltages Vo1 to Vo8 input from each signal line DL1 to DL8 to digital values.

The microcomputer 31 sends a command to the scanning-line drive circuit 32, and sequentially supplies the gate potentials Vg1 to Vg8 to the plurality of scanning lines SL1 to SL8, respectively. The microcomputer 31 sends a command to the AD converter circuit 33 at the timing of supplying the gate potentials Vg1 to Vg8 to the scanning lines SL1 to SL8, and sequentially acquires the output voltages Vo1 to Vo8 from the signal lines DL1 to DL8. As a result, the output voltage Vo corresponding to all the sensor elements 23 included in the sensor unit 22 can be acquired. Therefore, the change from the initial value of the resistance value of the variable resistance portion 24 in each sensor element 23 can be obtained from the value of each output voltage Vo, and the strain of each sensor element 23 can be detected.

The microcomputer 31 outputs the acquired data to the display device 50. The display device 50 displays, for example, information of the strain generated in the sensor main body 20 on the display screen 51. On the display screen 51, for example, square frames 52 corresponding to each of the 64 sensor elements 23 are displayed in an 8×8 matrix. The display device 50 is capable of displaying the distribution of the strain generated in the sensor main body 20 by changing the color in each frame 52 displayed on the display screen 51 in response the magnitude of the strain generated in each sensor element 23.

As a display form, each of the square frames 52 arranged in the 8×8 matrix is displayed as a three-dimensional (3D) bar graph, and when each of the 64 sensor elements 23 is in the strain-free state, the height of the bar graph for each frame 52 is aligned to a constant value (initial height), and the height of the bar graph of the frame 52 corresponding to the portion where the strain occurs among the 64 sensor elements 23 may be changed from the initial height according to the degree of the strain (the bending degree of the corresponding portion of the substrate 21).

According to the present embodiment, the variable resistance portion 24 has the extension portion 24e extending in one direction. Therefore, it is easy for the strain occurred in the extension portion 24e when the sensor element 23 is bent around an axis orthogonal to the extending direction of the extension portion 24e, while it is difficult for the strain occurred in the extension portion 24e when the sensor element 23 is bent around an axis parallel to the extending direction of the extension portion 24e. Accordingly, when the sensor element 23 is bent around the axis orthogonal to the extending direction of the extension portion 24e, it is easy for the resistance value of the variable resistance portion 24 to change, and when the sensor element 23 is bent around the axis parallel to the extending direction of the extension portion 24e, it is difficult for the resistance value of the variable resistance portion 24 to change. Thus, according to the sensor element 23 of the present embodiment, it is possible to detect the strain in a specific direction according to the direction in which the extension portion 24e extends from the strain generated in the sensor element 23. Therefore, for example, when it is desired to detect only the strain generated in the specific direction in the sensor element 23, it is possible to suppress the influence of the strain in the direction different from the specific direction, and the detection accuracy by the sensor element 23 can be improved. Therefore, according to the present embodiment, the detection accuracy of the flexible sensor 10 can be improved.

In the following description, the strain generated when the sensor element is bent around the axis orthogonal to the extending direction of the extension portion will be referred to as “the strain in the extending direction of the extension portion”, and the strain generated when the sensor element is bent around the axis parallel to the extending direction of the extension portion will be referred to as “the strain in the direction orthogonal to the extending direction of the extension portion”.

Furthermore, according to the present embodiment, the sensor element 23 has the transistor 25, and the variable resistance portion 24 is connected to the source electrode SE1 of the transistor 25. Therefore, by switching the state of the transistor 25 between the ON-state and the OFF-state, it is possible to switch between the state in which the current flows through the variable resistance portion 24 and the state in which the current does not flow through the variable resistance portion 24. As a result, it is possible to switch the sensor element 23 between a state in which the output voltage Vo that changes in response to the resistance value of the variable resistance portion 24 is detectable and a state in which the output voltage Vo is undetectable. Therefore, it is possible to configure the active-matrix type sensor unit 22 as described above by combining the plurality of sensor elements 23.

For example, it is conceivable that the distance (channel length) between the source electrode SE1 and the drain electrode DE1 in the transistor 25 changes slightly due to the strain generated in the sensor element 23. In this case, the resistance value between the source and drain of the transistor 25 changes when the current flows between the source electrode SE1 and the drain electrode DE1, and the output voltage Vo may change regardless of the magnitude of strain. More specifically, as the distance between the source electrode SE1 and the drain electrode DE1 becomes shorter, the resistance value of the transistor 25 becomes smaller and the output voltage Vo becomes larger. As the distance between the source electrode SE1 and the drain electrode DE1 becomes longer, the resistance value of the transistor 25 becomes larger and the output voltage Vo becomes smaller.

On the other contrary, according to the present embodiment, the source electrode SE1 and the drain electrode DE1 are arranged side by side in the direction (first direction) intersecting with the direction (second direction) in which the extension portion 24 extends. Therefore, even if the strain generated in the sensor element 23 is in the direction in which the extension portion 24e extends, it is difficult for the distance between the source electrode SE1 and the drain electrode DE1 to change. As a result, it is possible to prevent the detection accuracy of the flexible sensor 10 from being decreased when detecting the strain in the extending direction of the extension portion 24e.

Particularly in the present embodiment, the source electrode SE1 and the drain electrode DE1 are arranged side by side in the first direction intersecting with the second direction in which the extension portion 24 extends. Therefore, even if the strain generated in the sensor element 23 is in the direction in which the extension portion 24e extends, it is difficult for the distance between the source electrode SE1 and the drain electrode DE1 to change. As a result, it is possible to prevent the detection accuracy of the flexible sensor 10 from being decreased when detecting the strain in the extending direction of the extension portion 24e.

Furthermore, according to the present embodiment, a plurality of sensor elements 23 are provided. Therefore, when the sensor main body 20 is attached to the surface of a deformable measurement object by the plurality of sensor elements 23, it is possible to detect the strain in different parts of the measurement object. As a result, it is possible to accurately detect the strain of each part of the surface of the measurement target object.

Furthermore, according to the present embodiment, the active-matrix type sensor unit 22 in which the plurality of sensor elements 23 are arranged in the matrix shape is provided. Therefore, it is possible to detect the strain in each sensor element 23 with high accuracy by sequentially switching the transistor 25 of each sensor element 23 between the ON-state and the OFF-state. Moreover, the distribution of the strain generated in the sensor unit 22 can be easily obtained.

Furthermore, according to the present embodiment, in the plurality of sensor elements 23 included in the sensor unit 22, the extension portions 24e of the variable resistance portion 24 extend in the same direction as each other. Therefore, the strain in the same direction can be accurately detected for each different part of the measurement target object to which the sensor main body 20 is attached.

Furthermore, according to the present embodiment, the transistor 25 has the P-type channel (semiconductor layer) CA1. Therefore, when the transistor 25 is in the ON-state, the current flows from the source electrode SE1 to the drain electrode DE1 in the transistor 25. The variable resistance portion 24 is connected to the source electrode SE1, and the sensor unit 22 has the signal line DL to which the drain electrodes DE1 of at least two or more sensor elements 23 are connected. Therefore, even if the plurality of drain electrodes DE1 are connected to the signal line DL, the signal line DL and the variable resistance portion 24 can be electrically separated if the transistor 25 is in the OFF-state. As a result, by making only one transistor 25 in the sensor element 23 among the plurality of transistors 25 whose drain electrodes DE1 are connected to the signal line DL into the ON-state, it is possible to detect the output voltage Vo according to the sensor element 23 in which the transistor is in the ON-state without affecting the other variable resistance portions 24. Accordingly, it is possible to detect the strain of each sensor element 23 more accurately.

Furthermore, according to the present embodiment, the fixed resistance portion Ro connected to at least two or more drain electrodes DE1 via the signal line DLn (n=1 to 8) is provided. Therefore, the power supply voltage Vcc applied between the power supply electrode PL and the ground GND is divided and applied to each of the variable resistance portion 24, the transistor 25, and the fixed resistance portion Ro according to the resistance value of each configuration. As a result, it is possible to detect the change in the resistance value of the variable resistance portion 24 and detect the strain generated in the sensor element 23 by taking out the output voltage Vo applied to the fixed resistance portion Ro as the divided voltage. Further, as described above, since the signal line DLn (n=1 to 8) is shared by the plurality of sensor elements 23 arranged in the second direction (Y-axis direction) on the substrate 21, it is also possible to share the fixed resistance portions Ron (n=1 to 8) connected to each of the signal line DLn (n=1 to 8) to the plurality of sensor elements 23 arranged in the Y direction on the substrate 21. Therefore, the number of fixed resistance portions Ro can be reduced.

Furthermore, according to the present embodiment, the variable resistance portion 24 has the plurality of extension portions 24e. Therefore, when the strain occurs, it is possible to enlarge the change in the resistance value in the variable resistance portion 24 because the resistance value changes in the plurality of extension portions 24e. As a result, even in a case in which the generated strain is minute, the change in the resistance value in the variable resistance portion 24 can be enlarged to some extent so as to make the minute strain to be easily detected. Therefore, the detection sensitivity and the detection accuracy of the flexible sensor 10 can be further improved.

For example, when the resistance value of the variable resistance portion 24 is too small with respect to the resistance value of the transistor 25, even if the stain occurred in the sensor element 23 and the resistance value of the variable resistance portion 24 changes, it is concerned that the combined resistance value of the variable resistance portion 24 and the transistor 25 almost does not change, and the output voltage Vo applied to the fixed resistance portion Ro almost does not change. In this case, it is possible to be difficult to detect the strain generated in the sensor element 23.

On the contrary, according to the present embodiment, the variable resistance portion 24 is formed in the rectangular wavy shape in which the adjacent extending portions 24e are connected to each other. Therefore, it is easy to extend the total length of the variable resistance portion 24 so as to relatively increase the resistance value of the variable resistance portion 24. As a result, it is possible to prevent the resistance value of the variable resistance portion 24 from becoming too small with respect to the resistance value of the transistor 25. Therefore, when the strain occurred in the sensor element 23 and the resistance value of the variable resistance portion 24 changes, the output voltage Vo can be suitably changed, and the strain generated in the sensor element 23 can be suitably detected.

$$[ 0073 ]$$

Further, in the case in which the variable resistance portion 24 is formed in the rectangular wavy shape, when the strain occurs in the direction in which the extension portion 24e extends, the strain will occur in the plurality of extension portions 24e, and the resistance value of the entire variable resistance portion 24 tends to change significantly. On the other hand, when strain occurs in the direction orthogonal to the extending direction of the extension portion 24e, there are few parts where the strain occurs, and it is difficult for the resistance value of the entire variable resistance portion 24 to change. More specifically, in the present embodiment, when the strain occurs in the direction orthogonal to the extending direction of the extension portion 24e, the strain will occur in only one of the joining portion 24f and the connecting portions 24c and 24d, and it is difficult for the resistance value of the variable resistance portion 24 to change. Therefore, by forming the variable resistance portion 24 in the rectangular wavy shape, it is possible to detect the strain in the extending direction of the extension portion 24e with a better accuracy.

Further, according to the present embodiment, the interval at which the plurality of extension portions 24e are arranged in the variable resistance portion 24 that is formed in the rectangular wave shape is shorter than the length of the extension portion 24e. Therefore, in the direction orthogonal to the extending direction of the extension portion 24e, it is possible to keep the size of the entire variable resistance portion 24 small while arranging the plurality of extension portions 24e.

Further, according to the present embodiment, in the variable resistance portion 24 formed in the rectangular wavy shape, the plurality of extension portions 24e are arranged side by side at equal intervals. Therefore, it is easy to uniformly distribute the plurality of extension portions 24e in one sensor element 23. As a result, it is easy to accurately detect the magnitude of the strain regardless of which part of the sensor element 23 where the strain occurs.

Further, according to the present embodiment, the variable resistance portion 24 has the insulator 24a and the plurality of conductive particles 24b dispersed in the insulator 24a. Therefore, when the strain occurs in the variable resistance portion 24, the distance between the conductive particles 24b in the insulator 24a changes, and it is possible to change the resistance value of the variable resistance portion 24. Further, as described above, by forming the variable resistance portion 24 into the film shape on the substrate 21 as described in the present embodiment, it is possible to change the resistance value of the variable resistance portion 24 in both cases in which the substrate 21 is bent to be convex downward and the substrate 21 is bent to be convex upward. Therefore, by forming the variable resistance portion 24 in the film shape, it is possible to detect the bending direction of the substrate 21, that is, the direction of the strain from the magnitude of the output voltage Vo.

Further, according to the present embodiment, the material of the insulator 24a is the energy curable resin. Therefore, it is easy to form the variable resistance portion 24 by applying and curing the uncured insulator 24a in which the plurality of conductive particles 24b are dispersed. As a result, it is easy to form the variable resistance portion 24 in an arbitrary shape. Further, it is easy to form the variable resistance portion 24 in the film shape. For example, by using a thermosetting resin as the insulator 24a, the uncured insulator 24a can be easily cured by applying heat to form the variable resistance portion 24. Further, by using a photocurable resin as the insulator 24a, the uncured insulator 24a can be easily cured by irradiating with light such as ultraviolet rays or the like to form the variable resistance portion 24.

Further, according to the present embodiment, the transistor 25 is the thin film transistor. Therefore, the thickness of the sensor element 23 can be reduced, and the flexibility of the sensor main body 20 can be easily improved. As a result, it is easy for the sensor main body 20 to be stuck to the measurement target object.

Further, according to the present embodiment, the transistor 25 is the organic thin film transistor. Therefore, the channel CA1 can be an organic semiconductor, and it is possible to form the channel CA1 by using the coating process such as the inkjet method. Therefore, it is easy to manufacture the transistor 25. Further, the flexibility of the transistor 25 can be increased, and the flexibility of the sensor main body 20 can be easily increased. As a result, it is easier to stick the sensor main body 20 to the measurement target object.

### Second Embodiment

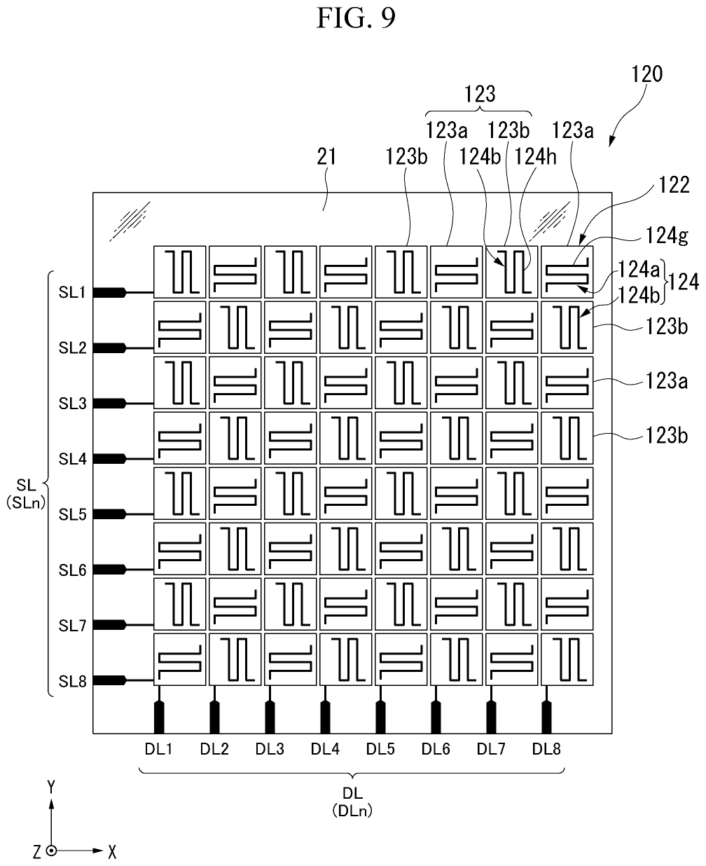

In the present embodiment, the configuration of the sensor unit 122 is different from that according to the first embodiment . FIG. 9 is a planar view showing the sensor main body 120 according to the present embodiment. In addition, with regard to the configuration being same as that according to the above-described embodiment, the description may be omitted by appropriately assigning the same reference numerals and the like.

As shown in FIG. 9, the plurality of sensor elements 123 included in the sensor unit 122 in the sensor main body 120 according to the present embodiment include a first sensor element 123a and a second sensor element 123b. In the present embodiment, the sensor unit 122 is an active-matrix type sensor unit in which a plurality of first sensor elements 123a and a plurality of second sensor elements 123b are arranged in a matrix. The plurality of first sensor elements 123a and the plurality of second sensor elements 123b are alternately arranged along the first direction (X-axis direction) and the second direction (Y-axis direction). That is, the plurality of first sensor element 123a and the plurality of second sensor element 123b are alternately arranged in each row of the matrix, and the plurality of first sensor element 123a and the plurality of second sensor element 123b are alternately arranged in each column of the matrix.

In a variable resistance portion 124a of the first sensor element 123a, an extension portion 124g extends in the first direction (X-axis direction). The variable resistance portion 124a has a rectangular wavy shape when viewed in a plane parallel to the XY plane. The variable resistance portion 124a has a shape by rotating the variable resistance portion 24 according to the first embodiment by 90 degrees around an axis extending in the thickness direction. Although it is not shown in figures, in the transistor included in a first sensor element 123a, the source electrode and the drain electrode are arranged side by side in the second direction (Y-axis direction) orthogonal to the first direction in which the extension portion 124g extends. Other configurations of the first sensor element 123a are the same as the configurations of the sensor element 23 according to the first embodiment.

A variable resistance portion 124b of the second sensor element 123b has an extension portion 124h extending in the second direction (Y-axis direction) different from the first direction (X-axis direction). The second sensor element 123b has the same configuration as the sensor element 23 according to the first embodiment.

Other configurations of the sensor main body 120 are the same as the configurations of the sensor main body 20 according to the first embodiment.

According to the present embodiment, the plurality of sensor elements 123 included in the sensor unit 122 include a first sensor element 123a having a variable resistance portion 124a in which the extension portion 124g extends in the first direction, and a second sensor element 123b having a variable resistance portion 124b having an extension portion 124h extending in the second direction different from the first direction. Therefore, it is possible to detect the strain (extension and contraction) in the first direction by the first sensor element 123a and detect the strain (extension and contraction) in the second direction by the second sensor element 123b. As a result, the sensor unit 122 can accurately detect the strains in the two different directions.

Further, according to the present embodiment, the plurality of first sensor element 123a and the plurality of second sensor element 123b are alternately arranged along the first direction and the second direction. Therefore, it is possible to uniformly distribute and arrange the plurality of first sensor elements 123a and the plurality of second sensor elements 123b in the sensor unit 122. As a result, both the strain in the first direction and the strain in the second direction can be suitably detected at any position of the sensor unit 122.

Further, according to the present embodiment, the second direction in which the extension portion 124h of the second sensor element 123b extends is the direction orthogonal to the first direction in which the extension portion 124g of the first sensor element 123a extends. Therefore, by detecting both the strain in the first direction and the strain in the second direction in the sensor unit 122, the direction and magnitude of the strain occurring in the sensor unit 122 can be detected with high accuracy.

The arrangement of the first sensor element 123a and the second sensor element 123b is not limited to the above-mentioned arrangement. For example, all of the sensor elements 123 arranged in the same row may be the same type of sensor elements 123. In this case, the row in which the plurality of first sensor elements 123a are arranged in the first direction (X-axis direction) and the row in which the plurality of second sensor elements 123b are arranged in the first direction may be alternatively arranged along the second direction (Y-axis direction). Further, for example, all of the sensor elements 123 arranged in the same row may be the same type of sensor elements 123. In this case, the row in which the plurality of first sensor elements 123a are arranged in the second direction and the row in which the plurality of second sensor elements 123b are arranged in the second direction may be alternately arranged along the first direction.

### Third Embodiment

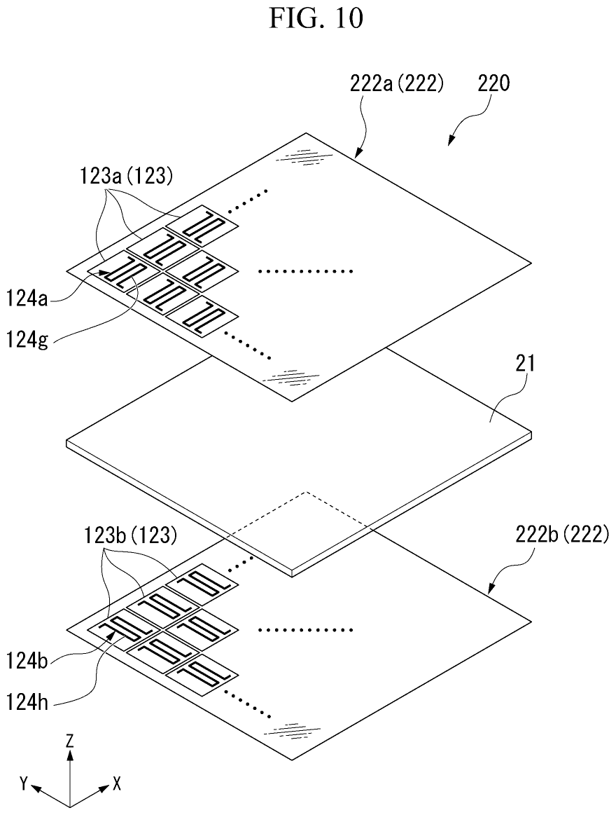

The present embodiment is different from the first embodiment in that a plurality of sensor units 222 are provided. FIG. 10 is an exploded perspective view showing the sensor main body 220 according to the present embodiment. In addition, with regard to the same configurations as the above-described embodiment, the description may be omitted by appropriately assigning the same reference numerals and the like.

As shown in FIG. 10, a plurality of sensor units 222 of the sensor main body 220 are provided according to the present embodiment. Two sensor units 222 are provided, for example, including a first sensor unit 222a and a second sensor unit 222b. The first sensor unit 222a is an active-matrix type sensor unit in which the plurality of first sensor elements 123a are arranged in a matrix. The second sensor unit 222b is an active-matrix type sensor unit in which the plurality of second sensor elements 123b are arranged in a matrix. As described in the second embodiment, the direction in which the extension portion 124g of the first sensor element 123a extends and the direction in which the extension portion 124h of the second sensor element 123b extends are different from each other. That is, according to the present embodiment, the direction in which the extension portions 124g and 124h of the variable resistance portions 124a and 124b (also generically referred to as the variable resistance portions 124) extend are different for each sensor unit 222.

The first sensor unit 222a and the second sensor unit 222b are arranged along a direction (Z-axis direction) orthogonal to a plane (XY plane) in which the sensor elements 123 are arranged in a matrix. The first sensor unit 222a is provided on the upper surface of the substrate 21. The second sensor unit 222b is provided on the lower surface of the substrate 21. As a result, at least one or more sensor elements 123 are provided on both sides of the substrate 21. The other configurations of the first sensor unit 222a and the other configurations of the second sensor unit 222b are the same as the configurations of the sensor unit 22 according to the first embodiment.

According to the present embodiment, the plurality of sensor units 222 are provided, and the directions in which the extension portions 124g and 124h of the variable resistance portions 124a and 124b extend are different for each sensor portion 222. Therefore, it is possible to accurately detect the strain generated in different directions for each sensor unit 222. As a result, it is possible to detect the strain of the measurement target object more accurately by the sensor main body 220.

Further, according to the present embodiment, the plurality of sensor units 222 are arranged along the direction orthogonal to the plane in which the sensor elements 123 are arranged in a matrix. Therefore, the plurality of sensor units 222 can accurately detect the strain (two-dimensional bending) in different directions that occurs at the same location of the measurement target object.

Further, according to the present embodiment, at least one or more sensor elements 123 are provided on both sides of the substrate 21. By providing the sensor elements 123 on both sides of the substrate 21 in this manner, it is easy to provide the plurality of sensor units 222 on the substrate 21.

The sensor elements 123 provided on both sides of the substrate 21 may be the same type of sensor elements 123. For example, the above-described first sensor unit 222a may be provided on both sides of the substrate 21, or the above-described second sensor unit 222b may be provided on both sides of the substrate 21. In this case, for example, when the substrate 21 is bent in the direction to be convex downward, the resistance value of the variable resistance portion 124 increases in the sensor unit 222 provided on the lower surface, and the resistance value of the variable resistance portion 124 decreases in the sensor unit 222 provided on the upper surface. Therefore, the strain detection sensitivity can be improved by using the difference between the output voltages Vo obtained from the two sensor units 222.

Further, the resistance value of the fixed resistance portion Ro connected to each of the plurality of sensor units 222 may be different from each other. In this case, the range of the magnitude of the detectable strain can be expanded. The details will be described below. The change in the resistance value of the variable resistance portion 124, that is, the magnitude of the strain is detected based on the output voltage Vo as the divided voltage applied to the fixed resistance portion Ro. Therefore, even if the resistance value of the variable resistance portion 124 is too small or too large with respect to the fixed resistance portion Ro, the output voltage Vo is less likely to change together with the change in the resistance value of the variable resistance portion 124, and it becomes difficult to detect the strain. In particular, when the resistance value of the variable resistance portion 124 changes exponentially, the resistance value of the variable resistance portion 124 tends to be significantly different from that of the fixed resistance portion Ro depending on the magnitude of strain. Therefore, there may be a region in which the strain is difficult to be detected.

On the other hand, by making the resistance value of the fixed resistance portion Ro different for each sensor unit 222, the range of the magnitude of the detectable strain for each sensor unit 222 can be made different. As a result, it is possible to expand the range of the magnitude of the detectable strain by detecting the strain using the output voltage Vo from the different sensor unit 222.

Further, the resistance value of the transistor 25 in the ON-state may be different for each of the plurality of sensor units 222. Since the output voltage Vo is determined by the resistance value of the variable resistance portion 124, the resistance value of the transistor 25 in the ON-state, and the resistance value of the fixed resistance portion Ro, it is necessary to adjust the balance of each resistance value so as to detect the strain within a wide range as possible. Here, the resistance value of the transistor 25 in the ON-state has less freedom degrees than other resistance values. Therefore, for example, the resistance value of the variable resistance portion 124 and the resistance value of the fixed resistance portion Ro when there is no strain occurred are determined according to the resistance value of the transistor 25. Accordingly, the range of the detectable strain is determined. Therefore, by making the resistance value of the transistor 25 in the ON-state different for each sensor unit 222, the range of the detectable strain can be made different for each sensor unit 222. As a result, the range of the magnitude of the detectable strain can be expanded by detecting the strain using the output voltages Vo from different sensor units 222 in response to the magnitude of the strain. In a case of changing the resistance value (resistance value between source and drain) of the transistor 25 in the ON-state, it is only necessary to change the semiconductor material forming the channel CA1 of the transistor 25.

Further, the plurality of sensor units 222 may be provided to be laminated on the same side surface of the substrate 21. The number of sensor units 222 may be equal to or more than three. For example, the sensor unit 122 according to the second embodiment may be provided on both sides of the substrate 21.

### Fourth Embodiment

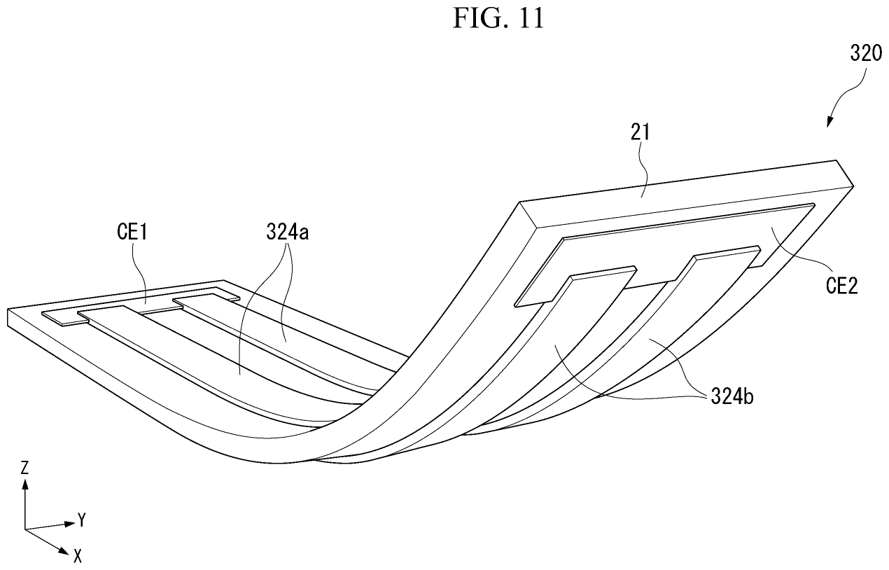

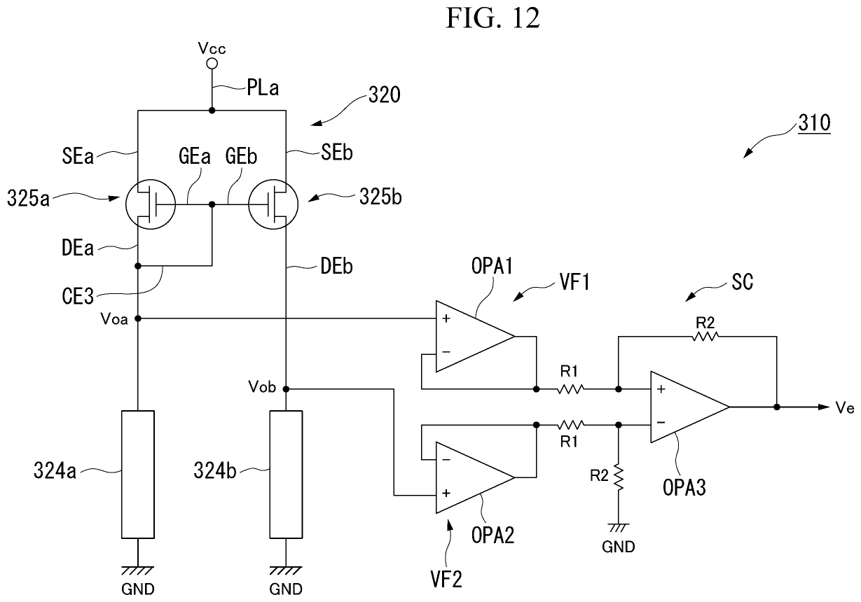

The present embodiment is different from the first embodiment in that the active-matrix type sensor unit is not provided. FIG. 11 is a perspective view showing a sensor main body 320 according to the present embodiment. FIG. 12 is a circuit diagram showing a part of the circuit configuration of a flexible sensor 310 according to the present embodiment. In addition, with regard to the configurations same as the above-described embodiment, the description may be omitted by appropriately assigning the same reference numerals and the like.

As shown in FIG. 11, the sensor main body 320 according to the present embodiment includes a variable resistance portion (extension portion) 324a provided on the upper surface of the substrate 21 and a variable resistance portion (extension portion) 324b provided on the lower surface of the substrate 21.

According to the present embodiment, the variable resistance portion 324a and the variable resistance portion 324b are extension portions extending in the first direction (X-axis direction). A pair of the variable resistance portions 324a and a pair of the variable resistance portions 324b are provided in the second direction (Y-axis direction), respectively. Both ends of the pair of variable resistance portions 324a are connected in parallel by the connection electrode CE1. Both ends of the pair of variable resistance portions 324b are connected in parallel by a connection electrode CE2.

According to the present embodiment, as shown in FIG. 12, the sensor main body 320 includes two transistors 325a and 325b. The two transistors 325a and 325b configure a current mirror circuit. The gate electrode GEa of the transistor 325a and the gate electrode GEb of the transistor 325b are connected to each other.

The source electrode SEa of the transistor 325a and the source electrode SEb of the transistor 325b are connected to a power supply electrode PLa to which a potential having a value of Vcc is supplied. The drain electrode DEa of the transistor 325a is connected to the variable resistance portion 324a in series. The drain electrode DEb of the transistor 325b is connected to the variable resistor portion 324b in series. That is, different from the first embodiment, the variable resistance portions 324a and 324b according to the present embodiment are connected to the drain electrodes DEa and DEb of the transistors 325a and 325b respectively.

The other ends of the variable resistance portions 324a and 324b are grounded to the ground GND. The gate electrodes GEa, GEb and the drain electrode DEa are connected by a connection electrode CE3. According to the current mirror circuit having such a configuration, the current with the same value is supplied to the variable resistance portion 324a and the variable resistance portion 324b.

In the flexible sensor 310 according to the present embodiment, it is possible to detect the strain generated in the sensor main body 320 from the potential at the drain electrode DEa, that is, the output voltage Voa applied to the variable resistance portion 324a, and the potential at the drain electrode DEb, that is, the output voltage Vob applied to the variable resistance portion 324b. The strain generated in the sensor body 320 can be detected.

The output voltage Voa is input to a subtraction circuit SC via a voltage follower VF1. The output voltage Vob is input to a subtraction circuit SC via a voltage follower VF2. The voltage follower VF1 has an operational amplifier OPAL in which the output voltage Voa is input to a non-inverting input terminal. The voltage follower VF2 has an operational amplifier OPA2 in which the output voltage Vob is input to a non-inverting input terminal.

The subtraction circuit SC has an operational amplifier OPA3, two resistors R1, and two resistors R2. The voltage value output from the voltage follower VF1 is input to the non-inverting input terminal of the operational amplifier OPA3 via the resistor R1. The portion between the non-inverting input terminal of the operational amplifier OPA3 and the resistor R1 is connected to the output terminal of the operational amplifier OPA3 via the resistor R2. The voltage value output from the voltage follower VF2 is input to the inverting input terminal of the operational amplifier OPA3 via the resistor R1. The portion between the inverting input terminal of the operational amplifier OPA3 and the resistor R1 is grounded to ground GND via the resistor R2.

The voltage Ve output from the output terminal of the operational amplifier OPA3 is represented by Ve={R2×(Vob−Voa)}/R1. In a case in which the output voltage Voa and the output voltage Vob are equal to each other, the voltage Ve is zero. The case in which the output voltage Voa and the output voltage Vob are the same is the case that there is no strain occurred in the sensor main body 320.

In the case in which the strain occurs in the sensor body 320, the output voltage Voa and the output voltage Vob have different values. For example, when the sensor main body 320 is bent in the direction as shown in FIG. 11, the variable resistance portion 324a contracts such that the resistance value thereof is reduced and the variable resistance portion 324b expands such that the resistance value thereof is increased. As a result, the output voltage Vob becomes larger than the output voltage Voa, and the voltage Ve becomes a positive value. Therefore, it is possible to detect that the strain occurs in the sensor body 320 from the voltage Ve.

On the other hand, when the sensor main body 320 is bent in a direction opposite to the direction as shown in FIG. 11, the variable resistance portion 324a expands such that the resistance value thereof is increased and the variable resistance portion 324b contracts such that the resistance value thereof is reduced. As a result, the output voltage Voa becomes larger than the output voltage Vob, and the voltage Ve becomes a negative value. Therefore, according to the present embodiment, it is possible to detect the direction of the strain generated in the sensor main body 320 by the positive or negative of the value of the voltage Ve. According to the present embodiment, since the variable resistance portions 324a and 324b are disposed on both sides of the substrate 21 respectively, the strain detection sensitivity can be improved.

The two transistors 325a and 325b as shown in FIG. 12 may be the thin film transistors (TFTs) such as the transistors 25 as shown in FIG. 5 and FIG. 6; however, the two transistors 325a and 325b may be the discrete Metal Oxide Semiconductor transistors (MOS) having the uniform characteristics. Further, the two transistors 325a and 325b may be junction type FETs or PNP-junction or NPN-junction bipolar transistors. Further, each of the two transistors 325a and 325b as shown in FIG. 12 may be changed to a fixed resistor.

The embodiment of the present disclosure is not limited to each of the above-described embodiments, and the following configurations can also be adopted.

At least one sensor element may be provided, and the number thereof is not particularly limited. The variable resistance portion of the sensor element may be connected to either of the gate electrode, the source electrode, and the drain electrode of the transistor. For example, according to the first embodiment, the variable resistance portion 24 may be connected to the drain electrode DE1. In this case, the channel CA1 of the transistor 25 may be N-type, and the positions of the source electrode SE1 and the drain electrode DE1 may be exchanged.

The variable resistance part may be connected to the gate electrode. In this case, the potential supplied to the gate electrode changes according to the change in the resistance value of the variable resistance portion. Therefore, the current value flowing between the source electrode and the drain electrode changes according to the change in the resistance value of the variable resistance portion. As a result, by detecting the change in the current value, it is possible to detect the change in the resistance value of the variable resistance portion and detect the strain.

The shape of the variable resistance portion only has to include one extension portion, and is not particularly limited. The variable resistance portion may have a plurality of extension portions extending in different directions from each other. The width of the extension portion, that is, the dimension in the direction orthogonal to both the extending direction and the thickness direction, does not have to be uniform. The variable resistance portion may be the rectangular wavy shape in which the amplitude magnitude changes, or may be the rectangular wavy shape with a changing period. The variable resistance portion may have a portion extending in a curved shape.

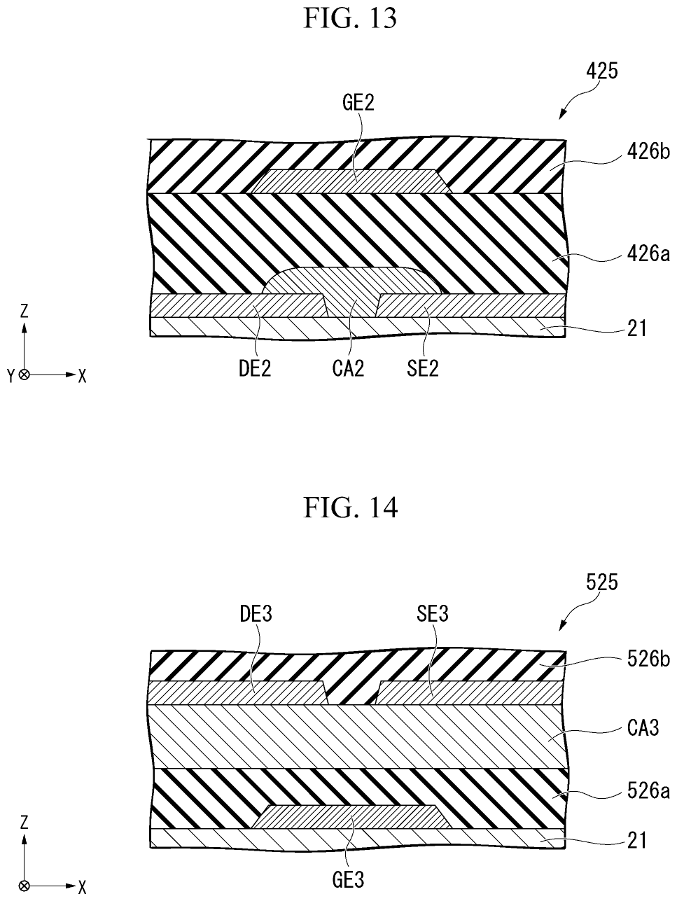

The structure of the transistor may be the structure of the transistor 425 as shown in FIG. 13 or the structure of the transistor 525 as shown in FIG. 14. FIG. 13 is a cross-sectional view showing the transistor 425 according to the first modification. FIG. 14 is a cross-sectional view showing the transistor 525 according to the second modification.

The transistor 425 shown in FIG. 13 is a top-gate type and bottom-contact type transistor. As shown in FIG. 13, in the transistor 425, the source electrode SE2, the drain electrode DE2, and the channel (semiconductor layer) CA2 are formed on the upper surface of the substrate 21. The gate electrode GE2 is formed on the upper surface of the insulating film 426a that covers the source electrode SE2, the drain electrode DE2, and the channel CA2 from the upper side. The gate electrode GE2 is covered from the upper side by an insulating film 426b.

The transistor 525 shown in FIG. 14 is a bottom gate type and top contact type transistor. As shown in FIG. 14, the gate electrode GE3 in the transistor 525 is formed on the upper surface of the substrate 21. The channel (semiconductor layer) CA3 is formed on the upper surface of the insulating film 526a that covers the gate electrode GE3 from the upper side. The source electrode SE3 and the drain electrode DE3 are formed on the upper surface of the channel CA3. The source electrode SE3 and the drain electrode DE3 are covered by the insulating film 526b from the upper side.

The type of transistor is not particularly limited. The transistor may be a thin film transistor other than the organic thin film transistor. The transistor may be a transparent thin film transistor.

The control unit 30 may be configured to be integrally provided with the sensor main body. In this case, the control unit 30 and the wiring unit 40 are disposed on the substrate, for example. In this case, the scanning-line drive circuit 32 may be directly connected to the scanning line SL, and the AD converter circuit 33 may be directly connected to the signal line DL without providing the wiring unit 40.

The manufacturing method of the flexible sensor is not particularly limited. The sensor main body may be formed by the dry process, or may be formed by both the wet process and the dry process.

The applications of the flexible sensor according to each of the above-described embodiments are not particularly limited. For example, the flexible sensor may be used as a sensor for detecting the strain in a bed. Since the flexible sensor according to the above-described embodiment can detect the strain in a specific direction, for example, it is possible to detect the three-dimensional strain of the bed by detecting the strain in the two directions orthogonal to each other at the position of each sensor element using the sensor main body as shown in the second embodiment and the third embodiment. Accordingly, for example, it is possible to detect the turning over from the strain of the bed, or deform the shape of the bed according to the strain of the bed, and the like. Further, the flexible sensor may be used as a sensor for measuring a change in the shape of the sail of a yacht.

Further, the flexible sensor may function as a sensor for detecting or measuring other parameters by detecting the strain of the measurement target object. For example, the flexible sensor may be a sensor configured to measure the three-dimensional shape of the measurement target object. In this case, the strain is generated in the sensor main body by sticking the sensor main body along the surface of the measurement target object. Therefore, for example, it is possible to detect the three-dimensional tilt of the measurement target object by detecting the strain in the two directions orthogonal to each other at the position of each sensor element using the sensor main body as shown in the second embodiment and the third embodiment. Accordingly, it is possible to measure the three-dimensional shape of the measurement target object.

Further, the flexible sensor may be a sensor for measuring the weight of the measurement target object. In this case, for example, the state in which the sensor main body of the flexible sensor is convex upward is referred to as a reference state. By setting the sensor main body in this state and placing the measurement target object on the upper side of the sensor main body, the sensor main body approaches the a flat state due to the weight of the measurement target object. It is possible to measure the weight of the measurement target object by detecting the change in the strain at this time.

Further, it is described that the flexible sensor according to each embodiment described above is the configuration used by being stuck to the measurement target object; however, the present disclosure is not limited thereto. For example, the sensor main body may not be stuck to the measurement target object and the sensor main body may be disposed in a flow path of a fluid such as a liquid or gas, and the flexible sensor may be used as a fluid sensor. The strain occurs in the sensor main body by contact with the fluid and it is possible to measure the magnitude of the flow of the fluid and the two-dimensional pressure distribution in the flow path. At this time, a plurality of through holes may be provided in the substrate 21 of the sensor main body, if necessary, so as to make the fluid to flow easily.

Several configurations and methods described in the present description may be appropriately combined within a range that does not contradict each other. The present disclosure is not limited to the above-described embodiments and is limited only by the accompanying claims.

What is claimed is:

1. A flexible sensor, comprising:
a substrate having flexibility; and
a sensor element provided on the substrate,
wherein the sensor element comprising:
a transistor having a gate electrode, a source electrode, and a drain electrode; and
a variable resistance portion connected to either of the gate electrode, the source electrode, and the drain electrode, and the variable resistance portion has a resistance value changeable due to a strain, and
wherein the variable resistance portion includes an extension portion extending in a direction.

2. The flexible sensor according to claim 1, wherein the source electrode and the drain electrode are arranged in a direction intersecting with the direction in which the extension portion extends.

3. The flexible sensor according to claim 2, wherein the source electrode and the drain electrode are arranged in a direction orthogonal to the direction in which the extension portion extends.

4. The flexible sensor according to claim 1, wherein a plurality of the sensor elements are provided.

5. The flexible sensor according to claim 4, wherein an active-matrix type sensor portion in which the plurality of sensor elements are arranged in a matrix shape is provided.

6. The flexible sensor according to claim 5, wherein the extension portions of the variable resistance portions in the plurality of sensor elements included in the sensor portion extend in the same direction with each other.

7. The flexible sensor according to claim 6, wherein a plurality of the sensor portions are provided, and the directions in which the extension portions extend respectively are different for each sensor portion.

8. The flexible sensor according to claim 7, wherein the plurality of sensor portions are arranged along a direction orthogonal to a plane in which the plurality of sensor elements are arranged in the matrix shape.

9. The flexible sensor according to claim 5,
wherein the plurality of sensor elements included in the sensor portion comprises
a first sensor element including the variable resistance portion with the extension portion extending in a first direction; and
a second sensor element including the variable resistance portion with the extension portion extending in a second direction different from the first direction.

10. The flexible sensor according to claim 9, wherein the first sensor element and the second sensor element are alternatively arranged in the first direction and the second direction.

11. The flexible sensor according to claim 9, wherein the second direction is orthogonal to the first direction.

12. The flexible sensor according to claim 5, wherein the transistor includes a P-type channel, the variable resistance portion is connected to the source electrode, and the sensor portion includes a signal line to which at least two or more drain electrodes of the sensor element are connected.

13. The flexible sensor according to claim 12, wherein a fixed resistance portion to which at least two or more drain electrodes are connected via the signal line.

14. The flexible sensor according to claim 4, wherein at least one or more sensor elements are provided in each surface at two sides of the substrate.

15. The flexible sensor according to claim 1, wherein the variable resistance portion includes a plurality of the extension portions.

16. The flexible sensor according to claim 15,
wherein the plurality of extension portions in the variable resistance portion extend in the same direction and are arranged at intervals therebetween in a direction orthogonal to the extending direction, and
the variable resistance portion is configured in a rectangle wavy shape in which the adjacent extension portions are connected to each other.

17. The flexible sensor according to claim 16, wherein the interval is shorter than a length of the extension portion.

18. The flexible sensor according to claim 16, wherein the plurality of extension portions in the variable resistance portion are arranged at equal intervals.

19. The flexible sensor according to claim 1, wherein the variable resistance portion includes an insulator and a plurality of conductive particles dispersed in the insulator.

20. The flexible sensor according to claim 19, wherein a material of the insulator is an energy curable resin.

21. The flexible sensor according to claim 20, wherein the energy curable resin is a thermosetting resin.

22. The flexible sensor according to claim 20, wherein the energy curable resin is a photocurable resin.

23. The flexible sensor according to claim 1, wherein the transistor is a thin film transistor.

24. The flexible sensor according to claim 23, wherein the transistor is an organic thin film transistor.
